(19) United States
(12) Patent Application Publication
(10) Pub. No.: US 2009/0035941 A1
(43) Pub. Date: Feb. 5, 2009

(54) METHODS AND APPARATUS FOR MANUFACTURING A SEMICONDUCTOR DEVICE IN A PROCESSING CHAMBER

(76) Inventors: Jin-Ho Park, Gyeonggi-do (KR); Gil-Heyun Choi, Seoul (KR); Sang-Woo Lee, Seoul (KR); Jun-Ho Park, Gyeonggi-do (KR); Ho-Ki Lee, Gyeonggi-do (KR)

Correspondence Address: MYERS BIGEL SIBLEY & SAJOVEC, PO BOX 37428, RALEIGH, NC, 27627, US

(21) Appl. No.: 12/183,421

(22) Filed: Jul. 31, 2008

(30) Foreign Application Priority Data
Aug. 1, 2007 (KR) 2007-77264

(51) Int. Cl. C23C 16/00; H01L 21/44

(52) U.S. Cl. 438/675; 118/723 E; 257/E21.476

(57) ABSTRACT

An apparatus for manufacturing a semiconductor device includes a process chamber configured to perform a plurality of different processes on a substrate. A gas supply unit is configured to supply at least one process gas to the process chamber. At least one upper electrode unit is positioned at an upper portion of the process chamber. At least one lower electrode unit is opposite the upper electrode unit and configured to support a substrate thereon. A driving member is connected to at least one of the lower electrode unit and the upper electrode unit and is configured to move the lower electrode unit and/or the upper electrode unit to control a distance between the upper and the lower electrode units. A power supply unit is configured to apply a first power to the upper electrode unit and to apply a second power to the lower electrode unit.

### RELATED APPLICATIONS

This application claims priority under 35 USC § 119 to Korean Patent Application No. 2007-77264, filed on Aug. 1, 2007 in the Korean Intellectual Property Office (KIPO), the contents of which are herein incorporated by reference in their entirety.

### FIELD OF THE INVENTION

The present invention relates to an apparatus for manufacturing a semiconductor device, and more particularly, to a deposition apparatus for manufacturing a semiconductor device.

### BACKGROUND

As semiconductor devices are becoming highly integrated, sizes of source/drain regions and widths of gate electrodes and metal wiring in semiconductor devices are being rapidly decreased. Particularly, the small widths of the metal wiring may cause an increase of the aspect ratio of a contact hole or a via hole, and thus there may be difficulties in filling up the contact hole or the via hole using conventional deposition processes. For that reason, planarization processes have been introduced for formation of the metal wiring in a semiconductor device as follows: A metal layer is formed on an insulation interlayer to a sufficient thickness to fill up the contact hole or the via hole using a conventional deposition process, and then the metal layer is planarized by the planarization process until a top surface of the insulation interlayer is exposed. As a result, only the metal layer remains in the contact hole or the via hole after the planarization process to thereby form the metal wiring structure for a semiconductor device. Recently, there has been a strong tendency to form a metal plug as the contact plug in place of a conventional polysilicon plug.

When a plug or a wiring includes a metal, a barrier layer along an inner surface of the contact hole or the via hole is usually required so as to prevent damage to underlying structures arranged under the insulation interlayer during formation of the plug or the wiring. Tungsten (W) has been widely used in deposition processes for forming the plug or the wiring and due to the relatively lower electrical resistance. However, tungsten may have many disadvantages in the formation process of the plug or the wiring in that a tungsten layer may have difficulty in adhering to an oxide layer and source gases in the deposition process for the plug or the wiring may cause damage to the inner surface of the contact hole or the via hole. In order to overcome the above potential disadvantages of the tungsten plug or the tungsten wiring, the barrier layer usually includes a glue layer along the inner surface of the contact hole or the via hole and an anti-diffusion layer on the glue layer. The anti-diffusion layer on the glue layer may reduce or prevent diffusion of the source gases such as fluorine (F) ions and the glue layer on the inner surface of the hole may reduce contact resistance of the plug or wiring in the contact hole or the via hole.

The anti-diffusion layer on the glue layer is transformed into a portion of the plug or the wiring, and thus generally needs to satisfy the following requirements of high uniformity and low contact resistance. That is, the anti-diffusion layer may be uniformly and evenly formed on the inner surface of a small space, such as the contact hole or the via hole, and may be formed to as small a thickness as possible so as to minimize the contact electrical resistance between the anti-diffusion layer and the metal plug. For the above requirements, a tungsten (W) layer is usually used as the glue layer, and a tungsten nitride (WN) layer is frequently used as the anti-diffusion layer.

The contact hole or the via hole is formed in the insulation interlayer that usually includes an oxide, and the barrier is formed on the inner surface of the contact hole or the via hole in such a configuration that a first tungsten layer is formed on the inner surface of the hole and a tungsten nitride layer is formed on the first tungsten layer. Then, a second tungsten layer is formed on the barrier layer to a sufficient thickness to fill up the hole, and a planarization process is performed on the second tungsten layer until a top surface of the insulation interlayer is exposed. Accordingly, only the second tungsten layer remains in the contact hole or the via hole in which the barrier layer is formed, to thereby form the contact plug or the metal wiring in the contact plug or the via hole.

However, the above conventional process for forming the contact plug and the metal wiring may have problems in that the first tungsten layer is typically removed from the insulation interlayer simultaneously with the second tungsten layer in the planatization process. Therefore, there may be a problem in that the contact hole or the via hole may not be sufficiently filled with the plug, and the plug may be spaced apart from the inner surface of the hole.

Various experimental results show that the first tungsten layer typically has been removed from the insulation interlayer at an upper portion of the contact hole or the via hole in the planarization process of the second tungsten layer for forming the plug structure, and the tungsten nitride layer has good etching resistance against a slurry for the planarization process, so that the plug structure is spaced apart from an upper portion of the inner surface of the hole by a gap distance corresponding to a thickness of the first tungsten layer. Therefore, the hole is not completely filled with the plug structure, and a void is generated between the plug structure and the upper portion of the inner surface of the hole. However, the electrical resistance of the tungsten nitride layer (functioning as de anti-diffusion layer) is generally much greater than that of the second tungsten layer (functioning as the metal wiring), so that replacement of the first tungsten layer by the tungsten nitride layer typically increases the electrical resistance of the contact plug or the metal wiring. Particularly, when the first tungsten layer is removed from a bottom of the contact hole or the via hole at which the plug structure makes contact with the silicon substrate, the contact resistance between the silicon substrate and the contact plug may be significantly increased, to thereby cause electrical shorts and device failures.

Semiconductor manufacturing methods in which an upper portion of the first tungsten layer is nitrated have been disclosed in Korean Patent Application No. 2006-125310, entitled “Metal Wiring Structure for a Semiconductor Device and Method of Forming the Same,” which corresponds to U.S. patent application entitled “Methods of Forming Electrical Interconnects Using Non-Uniformly Nitrified Metal Layers and Interconnects Formed Thereby”, application Ser. No. 11/778,344, filed Jul. 16, 2007. The disclosures of Korean Patent Application No. 2006-125310 and application Ser. No. 11/778,344 are hereby incorporated by reference in their entireties. The upper portion of the first tungsten layer is nitrated by a nitrification process while a lower portion of the tungsten layer is generally prevented from being nitrated in the nitrification process, so that the upper portion of the first tungsten layer is changed into a nitrated tungsten layer and the lower portion of the first tungsten layer still remains unchanged as a tungsten layer.

However, a first deposition process for forming the first tungsten layer, a nitration process for nitrating the upper portion of the first tungsten layer and a second deposition process for forming the tungsten nitride layer are each performed in an individual process chambers in the above metal wiring process, and thus, the substrate having the contact hole or the via hole is required to be transferred between the process chambers, which generates a vacuum break between each of the process chambers. The vacuum break in the metal wiring process increases costs and time of the process as well as deteriorates the quality of the deposition layer.

### SUMMARY

According to some embodiments of the present invention, an apparatus for manufacturing a semiconductor device includes a process chamber configured to perform a plurality of different processes on a substrate. A gas supply unit is configured to supply at least one process gas to the process chamber. At least one upper electrode unit is positioned at an upper portion of the process chamber. At least one lower electrode unit is opposite the upper electrode unit and is configured to support a substrate thereon. A driving member is connected to at least one of the lower electrode unit and the upper electrode unit and is configured to move the lower electrode unit and/or the upper electrode unit to control a distance between the upper and the lower electrode units. A power supply unit is configured to apply a first power to the upper electrode unit and to apply a second power to the lower electrode unit.

In some embodiments of the invention, the at least one upper electrode unit includes a plurality of the upper electrode units arranged at the upper portion of the process chamber and the at least one lower electrode unit comprises a plurality of the lower electrode units arranged to correspond to respective ones of the plurality of upper electrodes and provide a plurality of processing areas defined by spaces between respective ones of the plurality of upper electrode units and corresponding ones of the plurality of lower electrode units. The apparatus is configured to perform the plurality of different processes in respective processing areas substantially independently from one another. The gas supply unit can include a plurality of the gas supply units configured to correspond to respective ones of the plurality of upper electrodes and respective ones of the processing areas. The process gas can include a plurality of process gases that are individually supplied to each of the processing areas through the gas supply unit corresponding to each of the processing areas. The plurality of process gases can be substantially confined to respective ones of the processing areas. The processing areas can be separated from one another by a variable barrier in the process chamber, and the variable barrier can be configured to reduce the mixture of the process gases between each of the processing areas. The variable barrier can include an air curtain and/or an inactive gas curtain. The processing areas can include a first process area configured to perform a first deposition process for forming a metal layer along a surface of a pattern on the substrate, a second process area configured to perform a second deposition process forming a metal nitride layer along the surface of the pattern, and a third process area configured to perform a nitration process for nitating the metal layer and/or the metal nitride layer. The first and the second deposition processes can include a metal plasma process, a cyclic chemical vapor deposition (cyclic CVD) process, a pulsed nucleation layer (PNL) process and/or an atomic layer deposition (ALD) process, and/or the nitration process includes a nitrogen plasma process. The metal layer can include a tungsten layer and the metal nitride layer can include a tungsten nitride layer. A transfer unit can transfer the substrate between the process areas in the process chamber. The transfer unit can include a conveyor system and/or a transfer robot.

In some embodiments, the plurality of different processes are sequentially performed in the process chamber. The gas supply unit can include a plurality of gas reservoirs configured to store the process gases, a plurality of control valves configured to control an amount of the process gases discharged from each of the gas reservoirs and a supply pipe for supplying the process gases into the process chamber. The gas reservoirs can include a first reservoir in which a purge gas for cleaning the process chamber is stored and second, third and fourth reservoirs in which a metal source gas, a nitrogen source gas and a hydrogen source gas for forming a metal layer along a surface of a pattern on the substrate are stored, respectively, and the supply pipe can include a plurality of connection pipe lines connected to the first, second, third and fourth reservoirs, respectively, and a common supply pipe line commonly connected to each of the connection pipe lines. The process gases in each of the gas reservoirs can be discharged through the corresponding connection pipe line and can be supplied into the process chamber through the common supply pipe line. A central control unit (CCU) can be configured to control each of the control valves independently from one another in accordance with a sequential process order in the process chamber.

In some embodiments, the first power source includes an electric power source configured to transform the process gases into process plasma and the second power source includes a bias power source configured to accelerate the process plasma onto the substrate. The bias power source can generate a direct bias and a radio frequency (RF) bias.

In some embodiments, the driving member includes a first driving shaft part having a linear shaft connected to the lower electrode unit and a bearing supporting the linear shaft and configured to transfer driving power to the linear shaft from the driving power source. The driving power source can include an electrical motor. The driving member can include a second driving shaft part connected to the upper electrode unit and configured to move the upper electrode unit downwards to the lower electrode unit to thereby control a distance between the upper and lower electrode units in the process chamber.

In some embodiments, the upper electrode unit includes a first electrode electrically connected to the upper electrode unit and mechanically connected to the gas supply unit and a second electrode coupled with a lower surface of the first electrode to provide a buffer space between the first and second electrodes and configured to store the process gases before supplying the process gases to the process chamber. The lower electrode unit can include a heating member for heating the substrate. In some embodiments, the substrate comprises a pattern having an insulation interlayer on a conductive layer on the substrate and at least one contact hole penetrating the insulation interlayer.

According to some embodiments of the present invention, methods of forming a semiconductor device include depositing a metal layer in a contact hole on a substrate and nitratating a portion of the metal layer in single process chamber without a vacuum break.

### BRIEF DESCRIPTION OF THE DRAWINGS

Example embodiments will be more clearly understood from the following detailed description taken in conjunction with the accompanying drawings. FIGS. 1 to 3 represent non-limiting, example embodiments as described herein.

FIG. 1A is a cross-sectional view illustrating an apparatus for manufacturing a semiconductor device in according to embodiments of the present invention.

FIG. 1B is a plan view illustrating a bottom portion of the apparatus shown in FIG. 1A;

FIG. 1C is a view illustrating an upper portion of the apparatus shown in FIG. 1A;

FIG. 2 is a cross-sectional view illustrating a pattern on the substrate S according to embodiments of the present invention; and

FIG. 3 is a view illustrating an apparatus for manufacturing a semiconductor device according to embodiments of the present invention.

### DETAILED DESCRIPTION OF EMBODIMENTS ACCORDING TO THE INVENTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

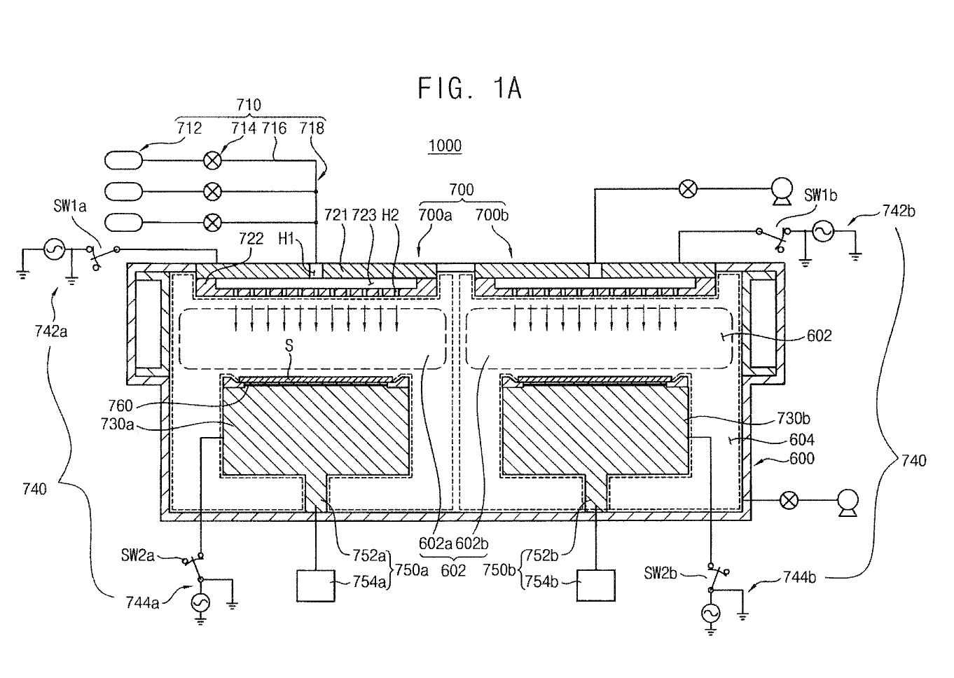

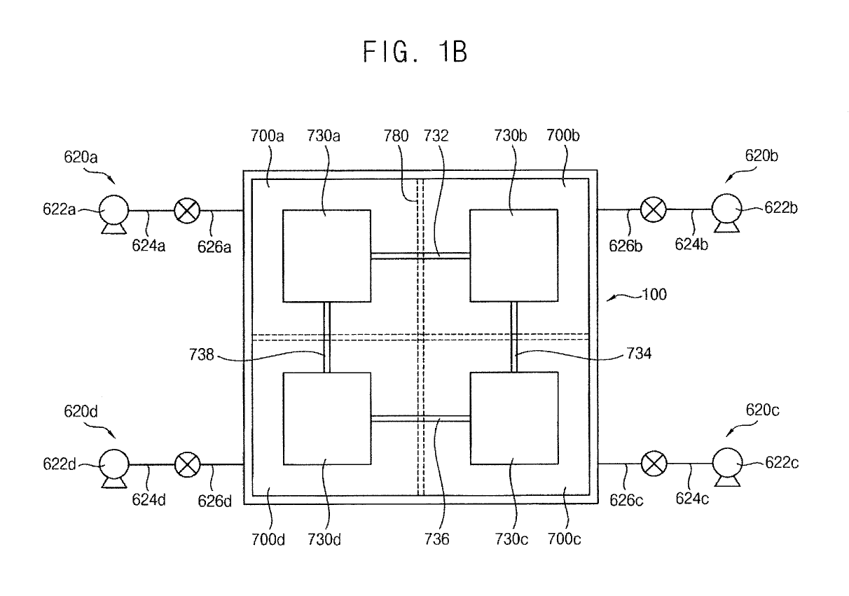

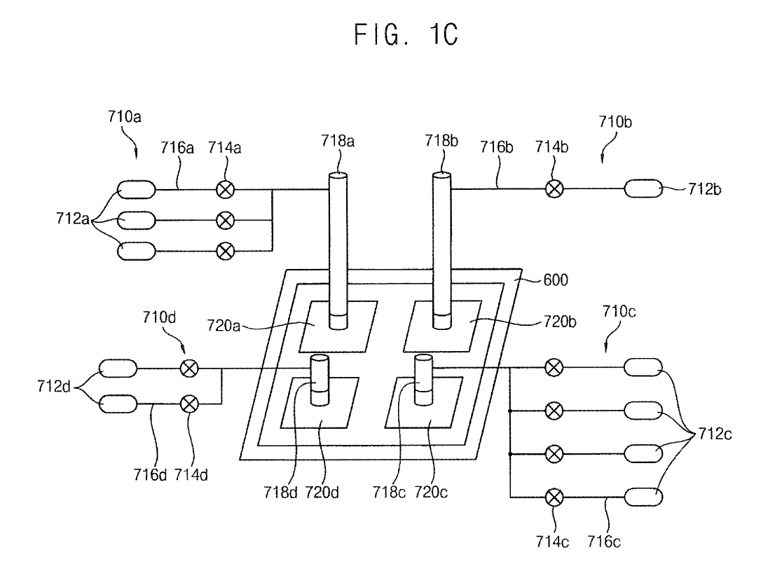

FIG. 1A is a cross-sectional view illustrating an apparatus 1000 for manufacturing a semiconductor device in accordance with an examplary embodiments of the present invention. FIG. 1B is a plan view illustrating a bottom portion of the apparatus shown in FIG. 1A and FIG. 1C is a view illustrating an upper portion of the apparatus shown in FIG. 1A.

Referring to FIGS. 1A to 1C, the apparatus 1000 for manufacturing a semiconductor device in accordance some embodiments of the present invention may include a process chamber 600 in which various processes, which are different from one another, are performed on a semiconductor substrate S having at least one pattern thereon.

In some embodiments, the processing units 700 may include a first unit 700a for performing a first process, a second unit 700b for performing a second process, a third unit 700c for performing a third process and a fourth unit 700d for performing a fourth process (See FIG. 1B). However, any number of processing units may be provided. The number of the processing units 700 may be varied in accordance with process characteristics of a semiconductor device, as would be known to one of ordinary skill in the art. Hereinafter, each of processing units 700 may have a similar structure, and thus it should be understood that the same reference numerals denote the analogous elements in each of the processing units 700. For example, although processing units 700a, 700b are illustrated in FIG. 1A, it should be understood that processing units 700c, 700d can include analogous elements similar to those shown with respect to processing units 700a, 700b. Each of the analogous elements in each of the processing units 700 is separated from one another by some suffixes that are added to the same reference numerals. As described with respect to FIGS. 1A-1C, a suffix ‘a’ is added to the same reference numerals so as to denote the same elements in the first processing unit 700a. A suffix ‘b’ is added to the same reference numerals so as to denote the same elements in the second processing unit 700b and a suffix ‘c’ is added to the same reference numerals so as to denote the same elements in the third processing unit 700c. A suffix ‘d’ is added to the same reference numerals so as to denote the same elements in the fourth processing unit 700d.

As shown in FIGS. 1A-1C, the processing units 700a-700d include gas suppliers 710a-710d for supplying a process gas for each of the processes into the process chamber 600, upper electrodes 720a-720d arranged at an upper portion of the process chamber 600 and connected to the corresponding gas suppliers 710a-710d and lower electrodes 730a-730d arranged at a lower portion of the process chamber 600 to correspond one-to-one to the upper electrodes 720a-720d. As illustrated in FIG. 1A with respect to the processing units 700a-700b, the units 700a-700b further include power suppliers 740 including first power sources 742a-742b for supplying an electrical power to the upper electrodes 720a-720b and a second power source 744a-744b for supplying an electrical power to the lower electrodes 730a-730b. It should be understood that the processing units 700c-700d may also include first and second power suppliers (not shown) and other features analogous to those shown respect to processing units 700a-700b. As illustrated in FIGS. 1A-1C, the substrate S is positioned on a surface of one of the lower electrodes 730a-730d.

As illustrated in FIG. 1A, each of the gas suppliers 710a-710d may supply the process gases for each process that may be individually performed in a process space between a pair of the upper and lower electrodes 720a-720d and 730a-730d. With reference to FIGS. 1A-1C, the upper electrodes 720a-720d may be coupled one-to-one to the lower electrodes 730a-730d, and thus the process space between the pair of the upper and lower electrodes 720a-720d and 730a-730d may function as an individual processing units 700l-700d. That is, a number of the processing units 700a-700d may be located in the process chamber 600, and each of the processing units 700a-700d may be separated from one another by a variable barrier 780 in the process chamber 600 as illustrated in FIG. 1B. Therefore, each of the processes may be performed in each of the processing units 700 independently from one another, e.g., such that mixing of the processing gases between processing units 700a-700d is reduced or substantially prevented.

The process chamber 600 may include a closed inner space in which various processes may be performed on the substrate S. For example, the process chamber 600 may include an upper space 602 in which a manufacturing process is performed on the substrate S by the process gases and a lower space 604 from which a residual of the process gases and by-products of the process are discharged. The lower space 604 may be connected to a pump system 620 for making the inner space of the process chamber 600 vacuous. A number of the pump systems 620a-620d may be installed to the processing units 700a-700d, respectively. Accordingly, the inner space of the process chamber 600 corresponding to the first to fourth processing units 700a-700d may be formed into a vacuum by the first to fourth pump systems 620a-620d.

The pump systems 620a-620d may include vacuum pumps 622a-622d for generating power for discharging the by-products from the inner space of the process chamber 600, and respective discharge pipes 624a-624d can be installed between the vacuum pumps 622a-622d and the lower space 604. Regulation valves 626a-626d for detecting and controlling an inner pressure of the process chamber 600. The pump systems 620a-620d may be operated at each of the processing units 700a-700d independently from one another, so that the process spaces of each of the processing units 700a-700d are individually formed into a vacuum, and process gasses are generally confined to respective processing units 700a-700d.

The gas suppliers 710a-710d may supply the process gases to each of the respective processing units 700a-700d in the process chamber 600. According to some embodiments, first to fourth gas suppliers 710a-710d may be installed one-to-one to the processing units 700a-700d; however, it should be understood that alternative gas supply configurations may be used. For example, as illustrated in FIGS. 1A and 1C, the gas supplier 710a-710d includes gas reservoirs 712a-712d for individually holding source materials for the process gases, respective control valves 714a-714d for individually controlling each of the gas reservoirs 712a-712d to thereby regulate a discharge amount of each source material from each of the gas reservoirs 712a-712d and connection pipes 716a-716d for supplying each of the source materials to respective supply pipes 718a-718d that are connected to each of the processing units 700a-700d. In some embodiments, the structures of each of the gas suppliers 710a-710d may be different from one another in accordance with the processes that are to be performed in each of the processing units 700a-700d, because the process gases supplied into each of the processing units 700a-700d may be varied in accordance with the desired process(es) that are to be performed in each of the processing units 700a-700d.

In some embodiments, a conductive structure and an insulation interlayer covering the conductive structure are formed on the substrate S and a contact hole is formed in the insulation interlayer to thereby expose the substrate S. A first metal layer is formed along a surface of the contact hole in the first processing unit 700a by a first deposition process, and a nitration process is performed on the upper portion of the first metal layer in the second processing unit 700b. Therefore, the upper portion of the first metal layer is nitrated at an upper portion of the contact hole by the nitration process in the second processing unit 700b. A metal nitride layer is formed on the first metal layer (of which the upper portion is nitrated) in the second processing unit 700b along the profile or surface of the contact hole by a second deposition process in the third processing unit 700c. Then, a second metal layer is formed in the contact hole by a second deposition process in the fourth processing unit 700d to thereby fill up the contact hole with the second metal layer.

For example, when an atomic layer deposition (ALD) process is performed for formation of the first metal layer in the first processing unit 700a, the first gas supplier 710a may include a number of gas reservoirs 712a for individually holding metal source gases, hydrogen source gas and purge gases. It should be understood that any number of gas reservoirs 712a can be used. For example, when a metal plasma process or a pulsed nucleation layer (PLN) process is performed for formation of the first metal layer in the first processing unit 700a, the first gas supplier 710a may include a single gas reservoir 712a for holding plasma source gases or nucleation source gases, as would be known to those having ordinary skill in the art. When the nitration process may be performed in the second processing unit 700b, the second gas supplier 710b may include a single gas reservoir 712b for holding nitrogen source gases. Further, when an ALD process is performed for formation of the metal nitride layer in the third processing unit 700c, the third gas supplier 710c may include a number of gas reservoirs 712c for individually holding metal source gases, hydrogen source gas and nitrogen source gas and purge gases. When a chemical vapor deposition (CVD) process is performed for formation of the second metal layer in the fourth processing unit 700d, the fourth gas supplier 710d may include a number of gas reservoirs 712d for individually holding metal source gases and carrier gases.

Each of the gas reservoirs 712a-712d in each of the gas supplier 710a-710d may be connected with the connection pipes 716a-716d, respectively, that are joined to the supply pipes 718a-718d connected to each of the processing units 700a-700d. The control valves 714a-714d may be installed to the connection lines 716a-716d, to thereby control the amount of each of the source gases in each of the gas reservoirs 712a-712d.

As illustrated in FIG. 1C, the first gas supplier 710amay include the gas reservoirs 712a, the connection pipes 716aconnected to the gas reservoirs 712a, respectively, and the control valves 714a installed to the connection pipes 716a, respectively. The second gas supplier 710b may include the single gas reservoir 712b, the single connection pipe 716b connected to the gas reservoir 712b and the single control valve 714b installed to the connection pipe 716b. The third gas supplier 710c may include the gas reservoirs 712c, the connection pipes 716c connected to the gas reservoirs 712c, respectively, and the control valves 714c installed to the connection pipes 716c, respectively. The fourth gas supplier 710d may include the gas reservoirs 712d, the connection pipes 716d connected to the gas reservoirs 712d, respectively, and the control valves 714d installed to the connection pipes 716d, respectively.

The first to fourth supply pipes 718a-718d may be connected to the first to fourth processing units 700a-700d, respectively, so that the process gases may be supplied to each of the processing units from the corresponding gas reservoirs irrespective of any other gas suppliers 710a-710d. Each of the control valves 714a-714d may individually control the amount of the source materials which are discharged from each of the gas reservoirs 712a-712d to the corresponding connection pipes 716a-716d.

In some embodiments, a central control unit (CCU) may control the opening and closing of each control valves 714a-714d in accordance with a sequential order of a manufacturing process in the process chamber 600.

Although FIGS. 1A-1C illustrate that that the process gases are individually supplied to each of the processing units 700a-700d through a corresponding gas supplier 710a-710d, a single common gas supplier may also be utilized for supplying the process gases to each of the processing units 700a-700d in place of the individual gas suppliers 710a-710d, as would be known to one of ordinary skill in the art. When the single gas supplier is utilized for supplying the process gases in place of a number of the gas suppliers, a number of di vergence pipe lines may be further installed between the single gas supplier and the processing units 700a-700d.

The upper electrodes 720a-720d may be at the upper portion of the process chamber 600, and the lower electrodes 730a-730d facing and corresponding one-to-one to the upper electrode 720a-720d may be arranged at the lower portion of the process chamber 600. The substrate S may be located on the surface of one of the lower electrodes 730a-730d. Therefore, the gas suppliers 710a-710d connected to the upper electrodes 720a-720d and the lower electrodes 730a-730d facing the upper electrode 720a-720d may be configured in the processing units 700a-700d together with the upper electrodes 720a-720d, and each of the processing units 700a-700d partially occupies the inner space of the process chamber 600.

It should be understood that the upper electrodes 720a-720d and lower electrodes 730a-730d may be formed in any suitable shape, such as a rectangle or a disc. As shown with respect to the upper electrodes 720ain processing unit 700a in FIG. 1A, the upper electrodes 720a-720d may each include a first electrode 721 positioned at an upper portion of the process chamber 600 and connected to a power source 742a and a second electrode 722 having a disc shape correspondently to the first electrode 721. The second electrode 722 may be coupled to a bottom surface of the first electrode 721 and positioned adjacent to the upper space 602. The upper electrode 720 may be connected to or disconnected from the power source 742 by a first switch Sw1a.

As further illustrated in FIG. 1A, a first penetration hole H1 is located at a central portion of the first electrode 721. The first penetration hole H1 may be connected to the supply pipe 718 of the gas supplier 710, so that the process gases or the purge gases may be supplied to the inner space of the process chamber 600 through the first penetration hole H1. Further, a buffer space 723 is formed between the first and the second electrodes 721 and 722, so that the process gases and the purge gases may be temporarily stored in the buffer space 723 before being supplied into the inner space of the process chamber 600.

Second penetration holes H2 are uniformly distributed on the second electrode 722, so that the process gases or the purge gases in the buffer space 723 may be uniformly supplied into the inner space of the process chamber 600 through the second penetration holes H2. A groove for forming the buffer space 723 is formed on an upper surface of the second electrode 722. Although the upper electrodes 720a-720d are described herein as having a disk shape, any other modification or suitable shape known to one of ordinary skill in the art may be used. For example, the upper electrode may have a coil shape.

According to some embodiments, the lower electrodes 730a-730d are positioned on a bottom portion of the process chamber 600 and the substrate S is located on the upper surface of the lower electrodes 730a-730d, which faces the upper electrodes 720a-720d, by a vacuum or an electrostatic force. Therefore, plasma is generated in the upper space 602 between the lower surface of the upper electrodes 720a-720d and the upper surface of the lower electrode 730a-730d, so that a portion of the upper space 602 between the lower surface of the upper electrodes 720a-720d and the upper surface of the lower electrode 730a-730d may be referred to as a plasma space. In addition, the residual process gases and by-products of the processes in the process chamber 600 are discharged from the lower space 604 between the bottom of the process chamber 600 and the upper surface of the lower electrodes 730a-730d, so that a portion of the lower space 604 between the bottom of the process chamber 600 and the upper surface of the lower electrodes 730a-730d may be referred to as a discharge space. A heal source 760 (FIG. 1A) may be further interposed between the substrate S and the upper surface of the lower electrodes 730a-730d, so that the temperature of the substrate S may be varied and controlled in accordance with process requirements in each of the processing units 700a-700d. For example, the heat source 760 may include an electric heater for transforming electrical energy to heat energy.

As illustrated in FIG. 1A with respect to processing units 700a-700b (noting that analogous features may be included in processing units 700c-700d), driving units 750a-b may be farther installed to a lower surface of the lower electrodes 730a-730b, so that the lower electrodes 730a-730b may move upward and downward in the process chamber 600 by the driving units 750a-750b. In some embodiments, the driving units 750a-750b may include respective first shafts 752a-752b connected to the respective lower electrodes 730a-730b and power sources 754a-754b electrically connected to the respective first shafts 752a-752b. The power source 754a-754b may apply rotation power to the first shafts 752a-752b and the lower electrodes 730a-730b can be moved upward or downward as the first shafts 752a-752b rotate with respect to a central axis thereof. For example, the first shafts 752a-752b may include a support unit for supporting the lower electrodes 730a-730b and a power transfer unit for transferring the rotation power to the support unit. The power transfer unit may include a bearing and a gear. The power sources 754a-754b may include a motor for generating an electric rotation power.

When the first lower electrode 730a is moved upward to the upper electrode 720a by the first driving shaft 752a in the first processing unit 700a, the size of the first plasma space 602a is reduced. Therefore, the substrate S in the first processing unit 700a may be substantially prevented from being influenced and/or contacted by the process gases or the plasma in the second to fourth plasma spaces 602b, 602c and 602d although different processes may be individually performed in the second to fourth processing units 700b, 700c and 700d.

A second driving shaft (not shown) may be further installed to the upper electrodes 720a-720d, and thus the upper electrodes 720a-720d may move downward or upward to or from the lower electrode 730a-730d. In some embodiments, when electric power is applied to the second driving shaft of the upper electrodes 720a-720d from a power source, the upper electrodes 720a-720d are moved towards the lower electrodes 730a-730d using the second driving shaft, and thus the size of the plasma space between the upper and lower electrodes 720a-720d and 730a-730d is reduced.

The power supplier 740 may supply electric power to the upper and lower electrodes 720a-720d and 730a-730d of each of the processing units 700a-700d. In some embodiments as illustrated in FIG. 1A with respect to the processing units 700a-700b, the power supplier 740 may include an electric power sources 742a-742b for generating the plasma from the process gases and bias power sources 744a-744b for accelerating the plasma from the substrate S. For example, the bias power sources 744a-744b may apply a direct current (DC) bias and/or a radio frequency (RF) bias to the lower electrodes 730a-730b. The electric power sources 742a-742b may be electrically connected to the first electrode 721 of the upper electrode 720 by the first switches Sw1a, Sw1b, and the bias power sources 744a-744b may be electrically connected to the lower electrodes 730a-730b by the second switches Sw2a-Sw2b. Therefore, the electric power sources 742a-742b and the bias power sources 744a-744b may be connected to the upper electrodes 720a-720b and the lower electrodes 730a-730b by the respective first and second switches Sw1a-Sw1b and Sw2a-Sw2b independently from each other, so that the electric power and the bias may be selectively and independently applied to the processing units 700a-700d in accordance with the process(es) that are to be performed. For example, the bias power may be merely applied to the lower electrodes 730b of the processing unit 700b in which the nitration process may be performed and may not be applied to the other lower electrodes 730a, 730c-730d of the other processing units 700a, 700c-700d. In such a case, when the nitration process is performed, for example, using nitration plasma in the second processing unit 700b, the nitrogen plasma is much more accelerated onto a top surface of the pattern rather than a bottom of the contact hole, to thereby perform a partial nitration process against the first metal layer.

A transfer unit may be arranged between the lower electrodes 730a-730d of each of the processing units 700a-700d, and thus the substrate S may move among the lower electrodes 730a-730d along the transfer unit. For example, a transfer unit may include conveyor systems 732, 734, 736 and 738 installed between the lower electrodes 730a-730d. When a process is completed on the substrate S in a processing unit, the substrate S is moved into the next processing unit according to a process sequence by the conveyor systems 732, 734. 736 and 738. For example, the substrate S may move in the process chamber 600 in a sequential order of first, second, third and fourth electrodes 730a-730d, respectively, to thereby complete the manufacturing process in the process chamber 600. In some embodiments, the first deposition process for forming the metal layer is performed in the first processing unit 700a and the nitration process is performed in the second processing unit 700b. The second deposition process for forming the metal nitride layer is performed in the third processing unit 700c and a metal plug process is performed in the fourth processing unit 700d. Therefore, when the substrate S moves in the above sequential order in the process chamber 600, the metal plug is formed in the contact hole in such a configuration that the barrier layer interposed between the metal plug and the insulation interlayer is partially nitrated at an upper portion thereof. In some embodiments, the transfer unit may include a transfer robot that may be installed in the process chamber 600. A robot arm of the transfer robot may reach the lower electrodes 730a-730d of each of the processing units 700a-700d and draw out the substrate S from the processing units 700a-700d. Then, the robot arm may transfer the completed substrate S to another lower electrode of the next processing unit in the sequential process order.

In some embodiments, the processing units 700a-700d may be separated from one another by a variable barrier 780 (FIG. 1B). For example, the variable barrier 780, such as an air curtain and an argon curtain, is arranged between the processing units 700a-700d, to thereby sufficiently prevent or reduce the mixture of the process gases between processing units 700a-700d and improve the independence of the process conditions between each of the processing units 700a-700d. In other words, a process gas can be substantially confined to one of the processing units 700a-700d.

Although embodiments are described herein with respect to a sequential process order of first to fourth processing units 700a-700d, any other process(es) and/or different orders known to one of the ordinary skill in the art may be utilized in place of the above sequential process order. For example, the sequential process order may be modified in such a manner that the second deposition process for forming the metal nitride layer is performed in the second processing unit 700b and the nitration process is performed in the third processing unit 700c, so that the nitration process may be performed on the barrier layer in which the metal layer and the metal nitride layer are included.

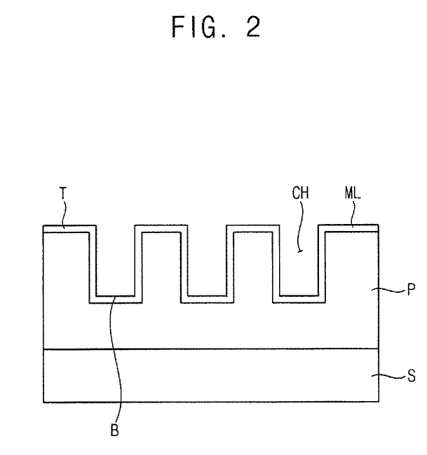

The above manufacturing apparatus 1000 for a semiconductor device may be operated as follows. FIG. 2 is a cross-sectional view illustrating a pattern on the substrate S in accordance with some embodiments of the present invention.

Referring to FIGS. 1A and 2, the substrate S is loaded into the process chamber 600 and is positioned on the first lower electrode 730a of the first processing unit 700a. At least one pattern P is formed on the substrate S in such a manner that an insulation interlayer covering a plurality of conductive structures on the substrate S is formed on the substrate S and a plurality of openings or contact holes CH partially exposing the conductive structures penetrates through the insulation interlayer. The substrate S may be loaded into the process chamber 600 by a transfer unit (not shown) such as a transfer robot, as would be known to one of the ordinary skill in the art. In some embodiments, the substrate S may be secured to the first lower electrode 730aby vacuum pressure and an electrostatic chuck.

Then, the inside pressure and temperature of the first processing unit 700a is controlled to optimal conditions for the process in the first processing unit 700a. Contaminants and residual materials are removed from the first processing unit 700a by the first pump system 620a, to thereby generate a first vacuum pressure in the first processing unit 700a. In some embodiments, the first vacuum pressure may be varied in a range of about 10 Torr to about 350 Torr. Then, the heater is operated in the first lower electrode 730a, and thus the substrate S is heated to a first temperature in a range of about 250° C. to about 350° C. The first deposition process is performed on the substrate S as a first process in the first processing unit 700a, to thereby form the first metal layer ML on the substrate S. In the some embodiments, the metal layer ML may include a tungsten (W) layer formed by an atomic layer deposition (ALD) process. Metal source gases and purge gases for the ALD process may be supplied into the first processing unit 700a by the first gas supplier 710a. The metal source gases may include tungsten (W) precursors. Examples of the tungsten (W) precursors may include one of WF6, WCl5, WBr6, WCo6, W(C2H2)6, W(PF3)6, W(allyl)4, (C2H5)WH2, [CH3(C5H4)2]2WH2, (C5H5)W(Co)3(CH3), W(butadiene)3, W(methyl vinyl ketone)3, (C5H5)HW(Co)3, (C7H8)W(Co)3, etc. These may be used alone or in combinations thereof. The purge gas may use an inert gas having high chemical stability such as helium (He), neon (Ne), argon (Ar), xenon (Xe) and nitrogen (N2). Periodically repeated supply of the metal source gases and the purge gases allows the first metal layer ML to have a proper thickness from a surface of the pattern P.

Although embodiments according to the present invention are described herein with respect to a first metal layer ML that is formed on the pattern P by the ALD process, any other processes for forming a thin layer on the pattern such as a metal plasma process and a pulsed nucleation layer (PNL) process may be utilized in place of the ALD process, as would be known to one of ordinary skill in the art. When the metal plasma process may be utilized in place of the ALD process, the metal source gases may be transformed into metal plasma by the electric power source 742a and a bias power is applied to the lower electrode 730a on which the substrate S is positioned by the bias power source 744a. Accordingly, the metal plasma may be accelerated onto the surface of the pattern P, and thus the first metal layer ML is uniformly formed along a surface of the contact hole in the pattern P.

When the first process for forming the first metal layer ML is completed on the substrate S, the substrate S including the first metal layer ML is transferred onto the second lower electrode 730b of the second processing unit 700b by the transfer unit.

In some embodiments, the inside conditions of the second processing unit 700b may be controlled for a second process of the nitration process. For example, the inside pressure of the second processing unit 700b may be controlled to about 0.1 Torr to about 10 Torr, and the substrate S may be heated to a temperature of about 300° C. to about 700° C. Nitrogen source gases may be supplied into the second plasma space 602b of the second processing unit 700b by the second gas supplier 710b and may be transformed into nitrogen plasma by the second electric power source 742b. For example, the electric power of about 1.3 MeV may be applied to the second upper electrode 721b by the second electric power source 742b and nitrogen gas or ammonium gas may be utilized as the nitrogen source gases. The second lower electrode 730b on which the substrate S is positioned may move upwards to the upper electrode 720b, to thereby reduce the size of the second plasma space 602b. Therefore, the plasma sheath in the second plasma space 602b only makes contact with the surface of the substrate S in the second processing unit 700b without any contact with any other substrates in other processing units in the process chamber 600.

In some embodiments, no bias power or a weak bias power may be partially applied to the lower electrode 730b by the second bias power source 744b in such a manner that the nitrogen plasma is distributed around an upper portion of the pattern much more intensively than around the substrate S exposed through the contact hole CH. That is, the nitrogen plasma is distributed around an upper portion T of the contact hole CH rather than around a lower portion B of the contact hole CH. Therefore, the first metal layer ML on the upper surface of the pattern and an upper sidewall of the contact hole CH may be nitrated in the nitration process, while the first metal layer ML on the bottom of contact hole CH and a lower sidewall of the contact hole CH may not be nitrated in the nitration process. Accordingly, an upper portion of the first metal layer ML may be merely nitrated and a lower portion of the first metal layer still remains without any nitration process, to thereby form a partially nitrated metal layer. Particularly, the first deposition process for forming the first metal layer and the nitration process may be continuously performed in the same process chamber without any alteration of the chamber, to thereby substantially prevent the vacuum break due to the chamber alteration.

While embodiments of the present invention are described herein with respect to the partially nitrated metal layer being formed by a plasma process using nitrogen source gases, any other processes such as an additional heat treatment may be utilized for the partial nitration to the first metal layer, as would be known to one of ordinary skill in the art. For example, the heat treatment to the substrate S at a temperature of about 300° C. to about 950° C. in nitrogen ambient may cause the upper portion of the first metal layer adjacent to the upper surface of the pattern to be nitrated in place of the nitrogen plasma process.

When the second process for forming the partially nitrated first metal layer is completed on the substrate S, the substrate S including the partially nitrated first metal layer is transferred onto the third lower electrode 730c of the third processing unit 700c by the transfer unit.

In some embodiments, the inside conditions of the third processing unit 700c may be controlled for a third process of the deposition process for forming the metal nitride layer. For example, the metal nitride layer may include a tungsten nitride (WN) layer formed by an ALD process, and thus the inside pressure of the third processing unit 700c may be controlled to about 0.1 Torr to about 350 Torr and the substrate S may be heated to a temperature of about 250° C. to about 550° C.

Metal source gases, purge gases, hydrogen source gases and nitrogen source gases may be supplied into the third processing unit 700c by the third gas supplier 710c, and thus the metal nitride layer is formed on the partially nitrated first metal layer along the surface of the contact hole CH. The metal nitride layer may be formed by the metal plasma process or the PNL process as well as the ALD process, as would be known to one of ordinary skill in the art. When the metal plasma process is utilized in place of the ALD process for forming the metal nitride layer, the bias power may be uniformly applied to the third lower electrode 730c by the bias power source 744c. That is, the bias power is applied to the lower electrode in such a manner that the bias power is uniformly distributed on a whole surface of the third lower electrode 730c.

When the third process for forming the metal nitride layer is completed on the substrate S, the substrate S including the metal nitride layer is transferred onto the fourth lower electrode 730d of the fourth processing unit 700d by the transfer unit.

In some embodiments, the inside conditions of the fourth processing unit 700d may be controlled for a fourth process of the second deposition process for forming the second metal layer. For example, the inside pressure of the fourth processing unit 700d may be controlled to about 10 Torr to about 350 Torr and the substrate S may be heated to a temperature of about 250° C. to about 550° C. The second metal layer may include tungsten (W) layer formed by an ALD process, a metal plasma process or a PNL process.

In some embodiments, metal source gases and purge gases may be supplied into the fourth processing unit 700d by the fourth gas supplier 710d, and thus the second metal layer is formed on the pattern to a sufficient thickness to fill up the contact hole. When the metal plasma process is utilized in place of the ALD process for forming the metal nitride layer, the bias power may be uniformly applied to the third lower electrode 730c by the bias power source 744c. That is, the bias power is applied to the lower electrode in such a manner that the bias power is substantially uniformly distributed on a whole surface of the third lower electrode 730c.

While some embodiments are described herein with respect to unit processes that are performed in such a sequential order that the metal nitride layer is formed on the partially nitrated first metal layer, the unit processes may be performed in any other sequential orders known to one of ordinary skill in the art. For example, the first metal layer and the metal nitride layer are sequentially formed along the surface of the contact hole on the substrate S, and then the nitration process may be performed against the metal nitride layer. That is, the metal nitride layer may be partially nitrated in the above nitration process in place of the first metal layer. The nitration process may be performed for improving polishing resistance of the barrier layer in a planarization process against the second metal layer for forming a metal plug, to thereby minimizing the gap distance between the metal plug and the sidewall of the contact hole. Therefore, which of the first metal layer or the metal nitride layer in the barrier layer is partially nitrated may be determined in accordance with characteristics of the semiconductor devices, and thus the nitration process may be performed on the first metal layer or the metal nitride layer.

According to some embodiments as illustrated by the apparatus 1000, the first deposition process, the partial nitration process and the second deposition process may be continuously performed in the same process chamber without any vacuum break, to thereby nitrate an upper portion of the barrier layer adjacent to the upper surface of the pattern. Accordingly, the barrier layer, which is interposed between the metal plug and the sidewall of the contact hole, may be substantially prevented from being removed from the pattern in the planarization process for forming the metal plug.

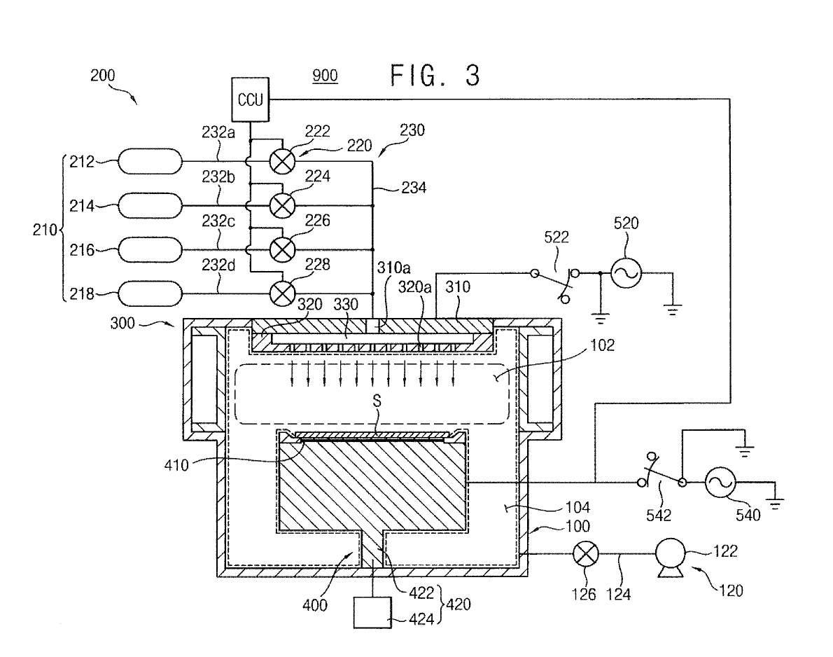

FIG. 3 is a view illustrating an apparatus 900 for manufacturing a semiconductor device in accordance with some exemplary embodiments of the present invention.

Referring to FIG. 3, the apparatus 900 for manufacturing a semiconductor device in accordance with some embodiments of the present invention may include a process chamber 100 in which various processes, which are different from one another, are performed on a semiconductor substrate S, a gas supply unit for supplying process gases into the process chamber 100, an upper electrode unit 300 connected to the gas supply unit 200 and positioned at an upper portion of the process chamber 100, a lower electrode unit 400 facing the upper electrode unit 300 and a power supply unit 500 for supplying a power to the upper and lower electrodes 300 and 400. The substrate S may be located on the lower electrode unit 400.

The process chamber 100 may include a closed inner space in which a plasmas process for forming a thin layer may be performed. The inner space of the process chamber 100 may include a plasma space 102 in which the processes gases are transformed into process plasma and the plasma process is performed on the substrate S using the process plasma and a discharge space 104 from which the residual process plasma and by-products of the plasma process to the substrate S are discharged out of the process chamber.

The discharge space 104 may be connected to a pump system 120, and thus the inner space of the process chamber 100 is formed into a vacuum state by the pump system 120. In some embodiments, the pump system 120 may include a vacuum pump 122 for generating a power for discharging the by-products from the inner space of the process chamber 100, a discharge pipe 124 installed between the vacuum pump 122 and the discharge space 104 and a regulation valve 126 for detecting and controlling an inside pressure of the process chamber 100.

The pump system 120 may be operated before or after each unit process is performed in the process chamber 100, so that the inner space of the process chamber 100 is formed into a vacuum state.

in some embodiments, the gas supply unit 200 may include gas reservoirs 210 for storing the process gases in accordance with each of the unit processes, respectively, control valves 220 for controlling each of the gas reservoirs 210 and regulating the amount of the process gases in each gas reservoir, respectively, and a supply pipe section 230 for supplying each of the process gases into the process chamber 100.

For example, the gas reservoirs 210 may include a first reservoir 212 in which purge gases for purging the inside of the process chamber 100 are stored and second, third and fourth reservoirs 214, 216 and 218 in which metal source gases, nitrogen source gases and hydrogen source gases are stored, respectively. The supply pipe section 230 may include connection lines 232a, 232b, 232c and 232d connected to the gas reservoirs 210, respectively, in such a manner that each of the process gases in one of the gas reservoirs may be discharged through a corresponding connection line regardless of the other gas reservoirs and a common supply line 234 commonly connected to each of the connection lines so that the processes gases in the gas reservoirs 210 may be supplied to the process chamber 100 through the common supply line 234. The control valves 232 are installed to the connection lines, respectively, so that the flow of the process gases in each of the gas reservoirs 210 may be individually controlled by each of the control valves 232.

In some embodiments, a CCU may control each of the control valves 222, 224, 226 and 228 independently from one another in accordance with a sequential process order in the process chamber 100.

The connection lines 232a-232d may be vertically arranged along the common supply line 234 in such a manner that the first connection line 232a through which the purge gases are supplied to the common supply line 234 is located at a top position in the vertical direction. Therefore, the purge gases may remove the residual process gases from most of the common supply line 234.

In some embodiments, the deposition process for forming a metal layer and the nitration process for partially nitrating the metal layer may be performed in the same process chamber 100. Particularly, when the lower electrode 400 move upwards to the upper electrode 300, the process plasma may be distributed around an upper surface of the pattern more intensively than a bottom portion of the contact hole.

The process gases may be supplied into the process chamber 100 through the upper electrode 300 and may be transformed into the process plasma by electric power applied to the upper electrode 300. The lower electrode 400 may support the substrate S and the process plasma may be guided onto the substrate S by a bias power applied to the lower electrode 400.

In some embodiments, the upper electrode 300 may be shaped into a disk and may include a first electrode 310 located at the upper portion of the process chamber 100 and to which the electric power is applied and a second electrode 320 shaped into the same disk as the first electrode 310 and coupled to a lower surface of the first electrode 310. The second electrode 320 may be positioned adjacent to the plasma space 102. The upper electrode 300 may be electrically connected to the electric power source 520 by a first switch 522.

A first penetration hole 310a is formed at a central portion of the first electrode 310, and thus the process gases or the purge gases may be supplied into the process chamber 100 through the first penetration hole 310a. In addition, a buffer space 330 is formed between the first and second electrodes 310 and 320, and thus the process gases or the purge gases may be temporarily stored in the buffer space before being supplied into the process chamber 100.

A plurality of second penetration holes 320a may be uniformly distributed on the second electrode 320, so that the process gases or the purge gases in the buffer space 330 may be uniformly supplied into the process chamber 100. A groove may be formed on an upper surface of the second electrode 320, and thus when a lower surface of the first electrode 310 and the upper surface of the second electrode 320 are coupled to each other, the groove is formed into the buffer space 330 of the upper electrode 300. While in some embodiments the first and second electrodes are shaped into the disk, any other modification such as a coil shape may be allowed to the first and second electrodes 310 and 320, as would be known to one of ordinary skill in the art.

The lower electrode 400 may be located at a bottom of the process chamber 100 and a driving unit 420 may be further installed to the lower electrode 400, so that the lower electrode 400 may be moved upward and downward by the driving unit. The substrate S may be secured to the lower electrode by vacuum pressure or an electrostatic force. As a result, the plasma space 102 may include a first portion of the inner space between the lower surface of the upper electrode 310 and the upper surface of the lower electrode 320, and the discharge space 104 may include a second portion of the inner space between the upper surface of the lower electrode 320 and the bottom of the process chamber 100. In addition, a heating unit 410 may be further located between the substrate S and the upper surface of the lower electrode 320, so that the substrate S is heated by the heating unit 410. For example, the heating unit 410 may include an electric heater for transforming electrical energy into thermal energy.

The driving unit 420 may be installed on the lower surface of the lower electrode 320, and thus the lower electrode 320 may be moved upwards to the upper electrode 310 by the driving unit 420 to thereby reduce the size of the plasma space 102. For example, the driving unit 420 may include a first driving section 422 connected to the lower surface of the lower electrode 320 and a power section 424 connected to the first driving section 422 and applying a driving power to the first driving section 422. The first driving section 422 may be rotated with respect to a central axis thereof by the driving power. When the first driving section 422 may be rotated by the power section 424, the lower electrode 320 may move upwards to the upper electrode 310, to thereby reduce the plasma space 102 between the first and second electrodes 310 and 320. In some embodiments, the first driving section 422 may include a linear shaft connected to the lower electrode 320 and a bearing supporting the linear shaft and transferring the rotational force to the linear shaft. The power section 424 may include an electrical motor. The driving unit 420 may further include a second driving section (not shown) connected to the upper electrode 310. The upper electrode 310 may move downwards to the lower electrode 320 by the second driving section, to thereby reduce the size of the plasma space 102 between the first and second electrodes 310 and 320.

The power supply unit 500 may include a first power source 520 for applying the electric power to the upper electrode 300 and a second power source 540 for applying a bias power to the lower electrode 400. The process gases may be transformed into the process plasma by the electric power and the process plasma may be guided onto the surface of the substrate S by the bias power applied to the lower electrode 400.

The first power source 520 may be electrically connected to the first electrode 310 of the upper electrode 300 by the first switch 522, and the second power source 540 may be electrically connected to the lower electrode 400 by the second switch 542.

In some embodiments, the second power source 540 may uniformly apply the bias power to the lower electrode 400, and thus the process plasma may be uniformly accelerated to the substrate S by the bias power. For example, when the plasma nitration process is performed on the metal layer that is formed on the pattern along the surface of the contact hole, the second switch 542 may be off in order that the bias power may not be applied to the lower electrode 320. Accordingly, the process plasma may be distributed at the upper surface of the pattern much more intensively than at the bottom of the contact hole, and thus an upper portion of the metal layer adjacent to the upper portion of the contact hole is nitrated in the nitration process. In such a case, the driving unit 420 may move the lower electrode 400 upwards to the upper electrode 300 and reduce the plasma space between the upper and lower electrodes 300 and 400. The reduction of the plasma space may accelerate the partial nitration against the upper portion of the metal layer much more than the lower portion of the metal layer at the bottom of the contact hole.

The above apparatus 900 shown in FIG. 3 may be operated as follows. The apparatus shown in FIG. 3 may be operated in the same manner as the apparatus 1000 shown in FIGS. 1A to 1C, except that a plurality of the unit processes are performed in the same single processing unit in the process chamber.

The substrate S is loaded into the process chamber 100 and is positioned on the lower electrode 400. The substrate S may be loaded into the process chamber 100 by a transfer unit (not shown) such as a transfer robot, as would be known to one of the ordinary skill in the art. In some embodiments, the substrate S may be secured to the lower electrode 400 by vacuum pressure and an electrostatic chuck.

Then, the inside pressure and temperature of the process chamber 100 is controlled to desired conditions for the first process. Contaminants and residual materials are removed from the process chamber 100 by the pump system 120, to thereby generate a first vacuum pressure for the first process. In some embodiments, the first vacuum pressure may be varied in a range of about 10 Torr to about 350 Torr. Then, the heating unit is operated in the first lower electrode 400, and thus the substrate S is heated to a first temperature in a range of about 250° C. to about 350° C. While some embodiments are described herein with respect to the heating unit directly heating the substrate S to the first temperature, any other heating process may also be utilized in place of or in conjunction with the heating unit, as would be known to one of ordinary skill in the art. For example, the inside of the process chamber 100 may be adjusted to the first temperature in advance by using an exterior heat source positioned at an outside of the process chamber 100 at the time when an inner pressure of the process chamber 100 is adjusted.

Then, the first deposition process is performed on the substrate S as a first process the process chamber 100, to thereby form the first metal layer on the substrate S. In some embodiments, the first metal layer may include a tungsten (W) layer formed by an ALD process. In such a case, the second control valve 224 is opened by the CCU, and thus the metal source gases stored in the second gas reservoir 214 is supplied into the process chamber 100. The metal source gases may include tungsten (W) precursors. Examples of the tungsten (W) precursors may include one of WF6, WCl5, WBr6, WCo6, W(C2H2)6, W(PF3)6, W(allyl)4, (C2H5)WM2, [CH3(C5H4)2]2WH2, (C5H5)W(Co)3(CH3), W(butadiene)3, W(methyl vinyl ketone)3, (C5H5)HW(Co)3, (C7H8)W(Co)3, etc. These may be used alone or in combinations thereof. Then, the second control valve is closed and the first control valve 222 is opened by the CCU, and thus the purge gases stored in the first gas reservoir 212 is supplied to the process chamber 100, to thereby purge the residual metal source gases out of the process chamber 100 (first purge process). The purge gas may use an inert gas having high chemical stability such as helium (He), neon (Ne), argon (Ar), xenon (Xe) and nitrogen (N2). The first control valve 222 is then closed and the fourth control valve 228 is opened by the CCU, and thus the hydrogen source gases stored in the fourth gas reservoir 218 is supplied to the process chamber 100. The hydrogen gases may be chemically reacted with the tungsten precursors that are chemisorbed onto the substrate S, so that chemical by-products of the tungsten precursors and the hydrogen gases are produced while the tungsten atoms still remain on the substrate S. Then, the fourth control valve is closed and the first control valve 212 is again opened by the CCU, so that the by-products are purged out of the process chamber 100 (second purge process). Periodical repetition of the above unit processes of the ALD process by the CCU allows the first metal layer to have a proper thickness from a surface of the pattern.

When the first process for forming the first metal layer is completed on the substrate S, the CCU controls the first control valve 222 to he opened, so that any contaminants and by-products of the first process are removed from the plasma space 102 of the process chamber 100, which is called as a first chamber cleaning process hereinafter. In some embodiments, extension of the second purge process may be utilized as the first chamber cleaning process, as would be known to one of ordinary skill in the art. However, when the first metal layer may be formed on the pattern by a PNL process or a metal plasma process, the first chamber cleaning process may be additionally performed for a sufficient time, so that the residual gases caused by the first process are removed from the process chamber 100.

The first control valve 212 is then closed and the first chamber cleaning process is completed. Thereafter, the inside pressure and temperature of the process chamber 100 is controlled to desired conditions for the nitration process. In some embodiments, the inside of the process chamber 100 is controlled to a pressure of about 0.1 Torr to about 10 Torr, and the substrate S is controlled to a temperature of about 300° C. to about 700° C. Then, the third control valve 226 is opened, so that the nitrogen source gases stored in the third gas reservoir 216 is supplied into the plasma space 102 of the process chamber 100. Electric power is applied to the upper electrode by the first power source 520, and thus the nitrogen source gases are transformed into the process plasma. For example, an electric power level of about 1.3 MeV is applied to the upper electrode 300 and nitrogen gases or ammonium gases may be used as the nitrogen source gases. In such a case, the lower electrode 400 on which the substrate S is located move upwards to the upper electrode 300, and the size of the plasma space 102 is reduced. Therefore, the process plasma may intensively be distributed on the surface of the substrate S, to thereby improve the reactivity of the first metal layer and the nitrogen plasma.

Accordingly, an upper portion of the first metal layer deposited on an upper surface of the pattern and an upper sidewall of the contact hole is nitrated in the nitration process and a lower portion of the first metal layer deposited on a lower sidewall of the contact hole in not nitrated in the nitration process. Therefore, the upper portion of the first metal layer is nitrated while the lower portion of the first metal layer is generally not nitrated or substantially free from nitration, to thereby form a partially or non-uniformly nitrated first metal layer on the pattern. The first process and the nitration process may be performed in the same process chamber without alteration of the chamber, to thereby prevent various defect factors such as the vacuum break.

When the nitration process for partially nitrating the first metal layer is completed on the substrate S, the CCU controls the first control valve 222 to be opened, so that any contaminants and by-products of the nitration process are removed from the plasma space 102 of the process chamber 100, which is called as a second chamber cleaning process hereinafter. The residual nitrogen gases and the nitrogen plasma are removed from the process chamber 100 by the second chamber cleaning process chamber.

The first control valve 212 is then closed and the second chamber cleaning process is completed. Thereafter, the inside pressure and temperature of the process chamber 100 is controlled to optimal conditions for the third process for forming a metal nitride layer. In some embodiments, the inside of the process chamber 100 is controlled to a pressure of about 0.1 Torr to about 350 Torr, and the substrate S is controlled to a temperature of about 250° C. to about 550° C.

Then, the metal source gases stored in the second gas reservoir 214, the purge gases stored in the first gas reservoir 212, the hydrogen source gases stored in the fourth gas reservoir 218, the purge gases stored in the first gas reservoir 212 and the nitrogen source gases stored in the third gas reservoir 216 are sequentially supplied into the process chamber 100. Therefore, a metal nitride layer is formed on the partially nitrated first metal layer along the surface of the contact hole by the ALD process.

While in some embodiments the metal nitride layer is formed by the ALD process, any other process for forming a thin layer such as a PNL process and a metal plasma process may be utilized in place of the ALD process. When the metal nitride layer is formed by the metal plasma process, the bias power is supplied to the lower electrode by the second power source 524 in such a manner that the bias power may be uniformly distributed on a whole surface of the substrate S.

When the third process for forming the metal nitride layer is completed on the substrate S, the CCU controls the first control valve 222 to be opened, and thus any nitrogen contaminants and by-products of the third process are removed from the process chamber 100, which is called as a third chamber cleaning process hereinafter. The residual nitrogen gases, the residual hydrogen gases, the residual purge gases and the by-products thereof are removed from the process chamber 100 by the third chamber cleaning process chamber.

The first control valve 212 is then closed and the third chamber cleaning process is completed. Thereafter, the inside pressure and temperature of the process chamber 100 is controlled to optimal conditions for the fourth process for forming a contact plug. In some embodiments, the inside of the process chamber 100 is controlled to a pressure of about 10 Torr to about 350 Torr, and the substrate S is controlled to a temperature of about 250° C. to about 550° C.

Then, the second control valve 224 is opened, so that the metal source gases stored in the second gas reservoir 214 is supplied into the process chamber 100. An electric power is applied to the upper electrode by the first power source 520, and thus the metal source gases are transformed into the process plasma. Then, the second metal layer is formed on the metal nitride layer to a sufficient thickness to fill up the contact hole on the substrate S by the metal plasma process. While the metal nitride layer is formed by the metal plasma process, any other process for forming a thin metal layer may be used in place of the metal plasma process, as would be known to one of ordinary skill in the art. For example, a cyclic CVD process may be used in place of the metal plasma process.

According to some embodiments of the apparatus 900 for manufacturing a semiconductor device, the first deposition process for forming the first metal layer, the partial nitration process for partially nitrating the first metal layer and the second deposition process for forming the metal nitride layer may be continuously performed in the same process chamber without any vacuum break, to thereby nitrate an upper portion of the barrier layer adjacent to the upper surface of the pattern. Accordingly, the barrier layer, which is interposed between the metal plug and the sidewall of the contact hole, may be substantially prevented from being removed from the pattern in the planarization process for forming the metal plug.

According to the exemplary embodiments of the present invention, a metal deposition process and a nitration process against the metal layer is performed in a single chamber without any alteration of the chambers, so that the metal deposition process and the nitration process may be continuously performed without any defect factors such as a vacuum break. In addition, a change to the sets of the CCU and a modification of the conveyor system may allow the sequential process orders of the unit processes to be altered in a single process chamber, to thereby facilitate the alteration of the sequential process orders.

The foregoing is illustrative of the present invention and is not to be construed as limiting thereof. Although a example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. An apparatus for manufacturing a semiconductor device, comprising:
a process chamber configured to perform a plurality of different processes on a substrate;
a gas supply unit configured to supply at least one process gas to the process chamber;
at least one upper electrode unit positioned at an upper portion of the process chamber;
at least one lower electrode unit opposite the upper electrode unit and configured to support a substrate thereon;
a driving member connected to at least one of the lower electrode unit and the upper electrode unit and configured to move the lower electrode unit and/or the upper electrode unit to control a distance between the upper and the lower electrode units; and
a power supply unit configured to apply a first power to the upper electrode unit and to apply a second power to the lower electrode unit.

2. The apparatus of claim 1, wherein the at least one upper electrode unit comprises a plurality of upper electrode units arranged at the upper portion of the process chamber and the at least one lower electrode unit comprises a plurality of lower electrode units arranged to correspond to respective ones of the plurality of upper electrodes and provide a plurality of processing areas defined by spaces between respective ones of the plurality of upper electrode units and corresponding ones of the plurality of lower electrode units, wherein the apparatus is configured to perform the plurality of different processes in respective processing areas substantially independently from one another.

3. The apparatus of claim 2, wherein the gas supply unit comprises a plurality of the gas supply units configured to correspond to respective ones of the plurality of upper electrodes and respective ones of the processing areas, and the process gas comprise a plurality of process gases that are individually supplied to each of the processing areas through the gas supply unit corresponding to each of the processing areas.

4. The apparatus of claim 3, wherein the plurality of process gases are substantially confined to respective ones of the processing areas.

5. The apparatus of claim 2, wherein the processing areas are separated from one another by a variable barrier in the process chamber, wherein the variable barrier is configured to reduce the mixture of the process gases between each of the processing areas.

6. The apparatus of claim 5, wherein the variable barrier includes an air curtain and/or an inactive gas curtain.

7. The apparatus of claim 2, wherein the processing areas include a first process area configured to perform a first deposition process for forming a metal layer along a surface of a pattern on the substrate, a second process area configured to perform a second deposition process forming a metal nitride layer along the surface of the pattern, and a third process area configured to perform a nitration process for nitrating the metal layer and/or the metal nitride layer.

8. The apparatus of claim 7, wherein the first and the second deposition processes include a metal plasma process, a cyclic chemical vapor deposition (cyclic CVD) process, a pulsed nucleation layer (PNL) process and/or an atomic layer deposition (ALD) process, and/or the nitration process includes a nitrogen plasma process.

9. The apparatus of claim 7, wherein the metal layer includes a tungsten layer and the metal nitride layer includes a tungsten nitride layer.

10. The apparatus of claim 2, further comprising a transfer unit for transferring the substrate between the process areas in the process chamber.

11. The apparatus of claim 10, wherein the transfer unit includes a conveyor system and/or a transfer robot.

12. The apparatus of claim 1, wherein the plurality of different processes are sequentially performed in the process chamber.

13. The apparatus of claim 12, wherein the gas supply unit includes a plurality of gas reservoirs configured to store the process gases, a plurality of control valves configured to control an amount of the process gases discharged from each of the gas reservoirs and a supply pipe for supplying the process gases into the process chamber.

14. The apparatus of claim 13, wherein the gas reservoirs include a first reservoir in which a purge gas for cleaning the process chunkier is stored and second, third and fourth reservoirs in which a metal source gas, a nitrogen source gas and a hydrogen source gas for forming a metal layer along a surface of a pattern on the substrate are stored, respectively, and the supply pipe includes a plurality of connection pipe lines connected to the first, second, third and fourth reservoirs, respectively, and a common supply pipe line commonly connected to each of the connection pipe lines, wherein the process gases in each of the gas reservoirs are discharged through the corresponding connection pipe line and are supplied into the process chamber through the common supply pipe line.

15. The apparatus of claim 13, further comprising a central control unit (CCU) configured to control each of the control valves independently from one another in accordance with a sequential process order in the process chamber.

16. The apparatus of claim 1, wherein the first power source includes an electric power source configured to transform the process gases into process plasma and the second power source includes a bias power source configured to accelerate the process plasma onto the substrate.

17. The apparatus of claim 16, wherein the bias power source generates a direct bias and a radio frequency (RF) bias.

18. The apparatus of claim 1, wherein driving member includes a first driving shaft part having a linear shaft connected to the lower electrode unit and a bearing supporting the linear shaft and transferring the driving power to the linear shaft from the driving power source, and the driving power source includes an electrical motor.

19. The apparatus of claim 18, wherein the driving member farther includes a second driving shaft part connected to the upper electrode unit and configured to move the upper electrode unit to control a distance between the upper and lower electrode units in the process chamber.

20. The apparatus of claim 1, wherein the upper electrode unit includes a first electrode electrically connected to the upper electrode unit and mechanically connected to the gas supply unit and a second electrode coupled with a lower surface of the first electrode to provide a buffer space between the first and second electrodes and configured to store the process gases before supplying the process gases to the process chamber, and the lower electrode unit further includes a heating member for heating the substrate.

21. The apparatus of claim 1, wherein the substrate comprises a pattern having an insulation interlayer on a conductive layer and at least one contact hole penetrating the insulation interlayer.

22. A method of forming a semiconductor device, the method comprising:
depositing a metal layer in a contact hole on a substrate and nitratating a portion of the metal layer in single process chamber without a vacuum break.
